(19) United States
(12) Patent Application Publication
(10) Pub. No.: US 2007/0011525 A1
(43) Pub. Date: Jan. 11, 2007

(54) SEMICONDUCTOR INTEGRATED CIRCUIT AND CONTROL METHOD THEREOF

(75) Inventor: Tomoaki Suzuki, Kawasaki-Shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/425,601

(22) Filed: Jun. 21, 2006

(30) Foreign Application Priority Data
Jun. 24, 2005 (JP) 2005-185799

(51) Int. Cl. G01R 31/28

(52) U.S. Cl. 714/726

(57) ABSTRACT

A semiconductor integrated circuit according to the present invention has a logical circuit network that implements predetermined processing, a plurality of scan chains that are penetrated through the logical circuit network and test the logical circuit network in a plurality of test modes, a plurality of shared terminals that share signals in a normal operating mode and in the plurality of the test modes, and input and output the signals, and a plurality of selectors that selectively switch one of a plurality of normal paths connected to the logical circuit network and one test path connected to the scan chain, and connect the switched path to one of the shared terminals. When the selector selects the test path in one test mode, the selector selects the normal path in the other test modes.

### BACKGROUND OF THE INVENTION

1. Field of the Invention

The present invention relates to a semiconductor integrated circuit and a control method thereof, and more particularly, to a semiconductor integrated circuit having a scan chain for test and a control method thereof.

2. Description of the Related Art

Recently, the circuit scale of a semiconductor integrated circuit trends to further increase. Therefore, a technology for efficiently testing the semiconductor integrated circuit has been regarded as important than ever.

As the technology for efficiently testing the semiconductor integrated circuit, a scan test is widely used.

In the semiconductor integrated circuit for scan test, all flip-flop circuits included in the semiconductor integrated circuit are cascade-connected and a scan chain is thus configured so that the semiconductor integrated circuit entirely functions as a shift register. In a so-called scan test, a test signal is externally input to the scan chain, test data is set to the flip-flop circuit forming the scan chain, a logical circuit of the semiconductor integrated circuit is operated, data of the flip-flop circuit that keeps the operating result is externally read out again with the scan chain. The scan test enables the efficient implementation of the test of the semiconductor integrated circuit.

In general, the increase in scale of the semiconductor integrated circuit causes a numerous number of the flip-flop circuits included therein. As a consequence, the scan chain from the input to the output becomes extremely long, and the setting of the test data and the reading of the test result take a long time, thereby requiring a long time for the scan test.

Further, for the purpose of reducing the time of scan test, it has been devised that a plurality of scan chains are disposed and the scan chains are tested in parallel therewith. However, the increase in number of scan chains also allows the rise in input/output terminals for the scan test. Therefore, when the number of pins in a package of the semiconductor integrated circuit is limited, advantages are not sufficiently obtained.

Conventionally, the above-mentioned problems have variously been examined. For example, Japanese Unexamined Patent Application Publication No. 2004-93433 (Patent Document 1) discloses a technology for performing an operating test of a semiconductor test circuit itself and an operating test that is directly performed to a tested circuit with the scan chain without increasing the number of output terminals.

Further, Japanese Unexamined Patent Application Publication No. 2000-9800 (Patent Document 2) discloses a technology for switching the configuration of the scan chains to the serial configuration or the parallel one in accordance with the form of the semiconductor integrated circuit (form of a wafer level, or a form thereof after packaging).

Furthermore, Japanese Unexamined Patent Application Publication No. 2004-37254 (Patent Document 3) discloses a technology for enabling the sharing of external terminals dedicated for the scan chain by disposing a switch for selectively changing-over input portions or output portions of a plurality of the scan chains disposed in parallel therewith and thus reducing the number of pins in the semiconductor integrated circuit.

The function of the semiconductor integrated circuit is further expanded, thereby increasing the number of input/output signals (hereinafter, referred to as a normal input/output signal) for achieving the original function of the semiconductor integrated circuit. Finally, the number of the normal input/output signals becomes close to the limitation of the number of pins of the package in the semiconductor integrated circuit. In this case, the pin of a test input/output signal (hereinafter, referred to as a scan input/output signal) cannot be dedicated for the scan test.

In order to solve the problem, such a technology has been devised that the pins of the normal input/output signal are distributed to the scan input/output signal in the scan test mode, and the same pin is shared to the normal input/output signal and the scan input/output signal.

The sharing of the same pin to the normal input/output signal and the scan input/output signal enables the implementation of the scan test without increasing the number of pins of the package.

In general, the semiconductor integrated circuit for executing the scan test comprises a logical circuit that achieves the original function and a single or a plurality of scan chains penetrated through the logical circuit.

In the case of independently setting the normal input/output signal and the scan input/output signal, the pin for the normal input/output signal is connected to the logical circuit, and the pin for the scan input/output signal is connected to an input terminal or an output terminal of the scan chain.

On the other hand, when the same pin (hereinafter, referred to as a shared terminal) is shared to the normal input/output signal and the scan input/output signal, a selector or the like needs to switch a path from the shared terminal to logical circuit and a path from the shared terminal to an input portion or an output portion of the scan chain. In the normal operating mode, the selector selects the path from the shared terminal to the logical circuit. On the other hand, in the scan test mode, the selector selects the path from the shared terminal to an input portion or an output portion of the scan chain.

Therefore, the scan test cannot realize the test of the path from the shared terminal to the logical circuit. If testing the path from the shared terminal to the logical circuit, a functional operation test needs to additionally be performed, independently of the scan test and the test time thus becomes long.

### SUMMARY OF THE INVENTION

The present invention is devised in consideration of the above-mentioned circumstances, and it is an object of the present invention to provide a semiconductor integrated circuit and a control method thereof, in which the scan test can test the wide range including the path from the shared terminal to the logical circuit with at a higher fault-detecting rate without using the functional operation test, even upon sharing a terminal for a normal input/output signal and a terminal for the scan test.

In order to solve the above-mentioned problems, according to a first aspect of the present invention, a semiconductor integrated circuit comprises: a logical circuit network that implements predetermined processing; a plurality of scan chains that are penetrated through the logical circuit network and test the logical circuit network in a plurality of test modes; a plurality of shared terminals that share signals in a normal operating mode and in the plurality of the test modes, and input and output the signals; and a plurality of selectors that selectively switch a normal path connected to the logical circuit network and a test path connected to the scan chain, and connect the switched path to the shared terminal, wherein, when the selector selects the test path in one test mode, the selector selects the normal path in the other test modes.

Further, in order to solve the above-mentioned problems, according to a fourth aspect of the present invention, a control method of a semiconductor integrated circuit having a logical circuit network that implements predetermined processing, a plurality of scan chains that are penetrated through the logical circuit network and test the logical circuit network in a plurality of test modes, a plurality of shared terminals that share signals in a normal operating mode and in a test mode, and input and output the signals; and a plurality of selectors that selectively switch a normal path connected to the logical circuit network and a test path connected to the scan chain, and connect the switched path to the shared terminal, comprises: selecting a test path in one test mode; and selecting a normal path in the other test modes.

### BRIEF DESCRIPTION OF THE DRAWINGS

FIG. 1 is a diagram showing an example of the configuration of a semiconductor integrated circuit according to a first embodiment of the present invention;

FIG. 2 is a diagram showing an operating mode table of the semiconductor integrated circuit according to the first embodiment of the present invention;

FIG. 3 is a diagram showing an example of the configuration of a semiconductor integrated circuit according to a second embodiment of the present invention;

FIG. 4 is a diagram showing an operating mode table of the semiconductor integrated circuit according to the second embodiment of the present invention;

FIG. 5 is a diagram showing an example of the configuration of a semiconductor integrated circuit according to a third embodiment of the present invention;

FIG. 6 is a diagram showing an operating mode table of the semiconductor integrated circuit according to the third embodiment of the present invention; and

FIG. 7 is a diagram showing an example of the configuration of a scan chain of a conventional semiconductor integrated circuit.

### DESCRIPTION OF THE PREFERRED EMBODIMENTS

Hereinbelow, a description is given of a semiconductor integrated circuit and a control method thereof according to embodiments of the present invention with reference to the accompanied drawings.

### (1) First Embodiment

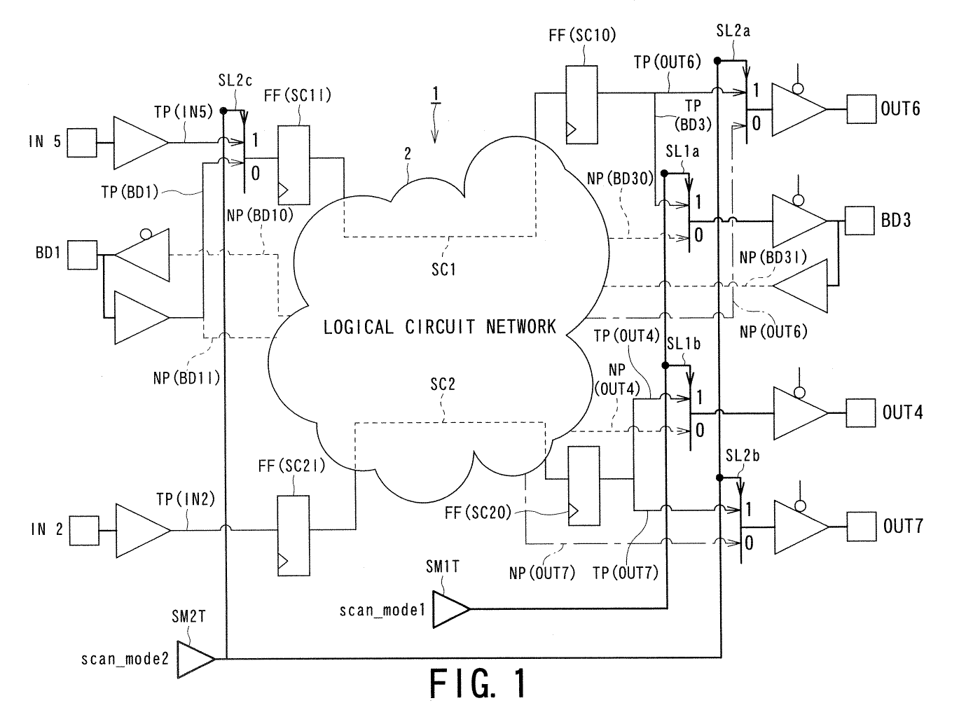

FIG. 1 is a diagram showing an example of a semiconductor integrated circuit 1 according to a first embodiment of the present invention.

The semiconductor integrated circuit 1 comprises a logical circuit network 2 that implements predetermined processing and a plurality of scan chains penetrating through the logical circuit network 2. Although the number of the scan chains is not particularly limited, in the example shown in FIG. 1, the semiconductor integrated circuit 1 comprises two scan chains SC1 and SC2.

Although predetermined processing of the logical circuit network 2 is not particularly limited, this may be, e.g., processing for controlling a DVD or predetermined image processing.

The scan chains SC1 and SC2 are disposed to test the logical circuit network 2 with a so-called scan test.

In general, the scan chains cascade-connect all flip-flop circuits included in the logical circuit network 2 and the entire the semiconductor integrated circuit thus functions as a shift register. With a so-called scan test, a test signal is externally input to the scan chains, test data is set to the flip-flop circuits forming the scan chains, and the logical circuit network 2 is tested.

In the cascade connection of all the flip-flop circuits included in the logical circuit network 2 with one scan chain, the scan chain is greatly long and the scan test requires a long time. Therefore, a plurality of the scan chains are disposed in parallel, thereby reducing the time of the scan test. In the example shown in FIG. 1, the two scan chains are disposed in parallel therewith.

The logical circuit network 2 includes a numerous number of flip-flop circuits that are sequentially cascade-connected by the scan chains SC1 and SC2. As shown in FIG. 1, the flip-flop circuits in the logical circuit network 2 are omitted, and only the flip-flop circuits disposed to both the ends of the scan chains SC1 and SC2 are shown. As specifically shown in FIG. 1, the flip-flop circuit includes a flip-flop circuit FF (SC1I) disposed to an input of the scan chain SC1, a flip-flop FF (SC1O) disposed to an output of the scan chain SC1, a flip-flop FF (SC2I) disposed to an input of the scan chain SC2, and a flip-flop FF (SC2O) disposed to an output of the scan chain SC2.

Signals are input and output to the logical circuit network 2 and the scan chains SC1 and SC2 from a numerous number of input/output terminals disposed to the semiconductor integrated circuit 1. The input/output terminals include not only a terminal dedicated for input and a terminal dedicated for output but also bi-directional input and output terminals.

In the example shown in FIG. 1, reference symbols IN2 and IN5 denote input terminals, and reference symbols OUT4, OUT6, and OUT7 denote output terminals, and reference symbols BD1 and BD3 denote bi-directional terminals.

Further, conventionally, when the number of pins of the semiconductor integrated circuit is not limited, the semiconductor integrated circuit independently has input and output terminals direct to the logical circuit network 2 and input and output terminals to the scan chain. However, the complication and variation of the functions of the logical circuit network 2 increase the number of input and output signals. In this case, under the limitation of the number of package pins of the semiconductor integrated circuit 1, necessarily, the semiconductor integrated circuit 1 shares the input and output terminals direct to the logical circuit network 2 and input and output terminals to the scan chain.

In the example shown in FIG. 1, the terminals IN5 and IN2 are distributed to the input terminals of the scan chain SC1 and the scan chain SC2. However, all the terminals BD1, BD3, OUT4, OUT6, and OUT7, other than IN5 and IN2, are shared to the input and output terminals direct to the logical circuit network 2 and the input and output terminals to the scan chain.

When the input and output terminals of the semiconductor integrated circuit 1 are the shared terminal, input and output paths to the scan chains SC1 and SC2 (hereinafter, referred to as test paths) and input and output paths to the logical circuit network 2 (hereinafter, referred to as normal paths) need to be switched in the scan test mode and the normal operating mode.

According to the first embodiment, in order to perform the switching operation, five selectors SL1a, SL1b, SL2a, SL2b, and SL2c are set, as shown in FIG. 1. Switching control signals of the selectors are fed from a scan mode (1) (scan_mode 1) terminal SM1T and a scan mode (2) (scan_mode 2) terminal SM2T disposed to the semiconductor integrated circuit 1.

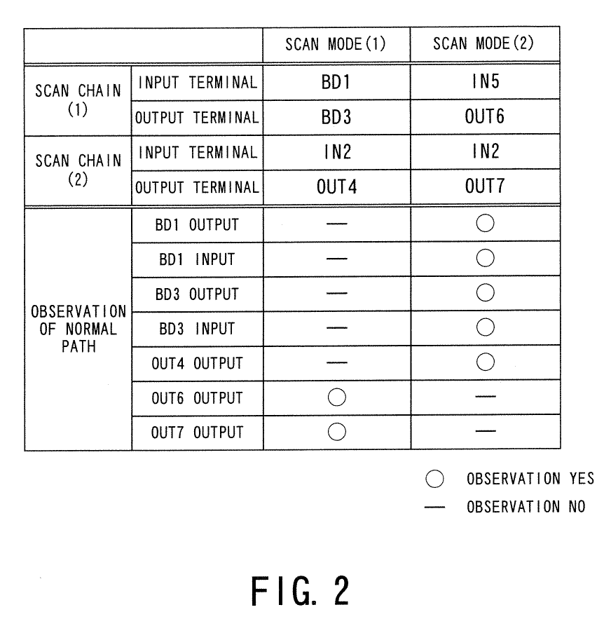

A description is given of the operation of the semiconductor integrated circuit 1 with the above-mentioned configuration with reference to the diagram showing the configuration shown in FIG. 1 and an operating mode table shown in FIG. 2.

With the semiconductor integrated circuit 1 according to the first embodiment, the scan test for the two scan chains SC1 and SC2 is performed in the two scan modes (1) and (2).

In the operating mode table (FIG. 2), first to fourth rows show terminals distributed to the input and output terminals of the scan chains in the scan modes (1) and (2).

Specifically, in the scan mode (1), the bi-directional terminal BD1 is distributed, as the input terminal of the scan chain SC1, and the bi-directional terminal BD3 is distributed, as the output terminal thereof. Further, the input terminal IN2 is distributed, as the input terminal of the scan chain SC2, and the output terminal OUT4 is distributed, as the output terminal thereof.

On the other hand, in the scan mode (2), the input terminal IN5 is distributed, as the input terminal of the scan chain SC1, and the output terminal OUT6 is distributed, as the output terminal thereof. Further, the input terminal IN2 is distributed, as the input terminal of the scan chain SC2, and the output terminal OUT7 is distributed, as the output terminal thereof.

The terminals in the scan modes (1) and (2) are distributed by switching the selectors SL1a, SL1b, SL2a, SL2b, and SL2c.

In the scan mode (1), the selectors SL1a and SL1b are switched to “1” and the selectors SL2a, SL2b, and SL2c are switched to “0”.

As a consequence, a connecting relationship between the terminals among the terminals in the scan mode (1), the logical circuit network 2, and the scan chains SC1 and SC2 is set as follows.

Since the selector SL2c is switched to “0”, the input terminal IN5 is not connected. In this case, a test path TP(BD1) is selected, thereby connecting the shared terminal BD1 to the input terminal of the scan chain SC1.

The input terminal IN2 is connected to the input terminal of the scan chain SC2 via a test path TP(IN2).

The shared terminal BD3 and OUT4 are connected to test paths TP(BD3) and TP(OUT4) by switching the selectors SL1a and SL1b to “1”.

Thus, the input terminal of the scan chain SC1 is connected to the shared terminal BD1 and the output terminal of the scan chain SC1 is connected to the shared terminal BD3. The input terminal of the scan chain SC2 is connected to the input terminal IN2, and the output terminal of the scan chain SC2 is connected to the shared terminal OUT4.

In the scan mode(1), the selectors SL2a and SL2b are switched to “0”, thereby connecting the shared terminals OUT6 and OUT7 to the logical circuit network 2 via normal paths NP(OUT6) and NP(OUT7).

The scan test in the scan mode (1) is performed with the above-mentioned connecting relationship.

In the scan test in the scan mode (1), obviously, the test paths TP(BD1), TP(BD3), and TP(OUT4) connected to the shared terminal BD1, BD3, and OUT4 are tested.

However, the normal paths between the shared terminal BD1, BD3, and OUT4 and the logical circuit network 2 are shut-off by the selectors, cannot be therefore observed, and remain as parts that cannot be test by the scan test in the scan mode (1).

Note that the shared terminal OUT6 and OUT7 are connected to the logical circuit network 2 via the selectors SL2a and SL2b and the normal paths can be observed even during the scan test in the scan mode (1).

Fifth to eleventh rows in the operating mode table shown in FIG. 2 indicate whether or not the normal path can be observed every shared terminal during the scan test. A case in which the normal path cannot be observed is indicated by symbol “—”, and a case in which the normal path can be observed is indicated by “◯”.

The scan test in the scan mode (1) ends and the scan test in the scan mode (2) is thereafter implemented.

In the scan mode (2), the selectors SL1a and SL1b are switched to “0” and the selectors SL2a, SL2b, and SL2c are further switched to “1”.

As a consequence, the connecting relationship between the terminals, the logical circuit network 2, and the scan chains SC1 and SC2 in the scan mode (2) are changed as follows.

That is, the selector SL2c is switched to “1”, thereby connecting the input terminal IN5 to the input terminal of the scan chain SC1. In this case, the input and output terminals of the shared terminal BD1 are connected to the logical circuit network 2 via normal paths NP(BD1O) and NP(BD1I).

Similarly to the scan mode (1), the input terminal IN2 is connected to the input terminal of the scan chain SC2 via the test path TP(IN2).

The selectors SL1a and SL1b are switched to “0”. Therefore, the input and output terminals of the shared terminal BD3 is connected to the logical circuit network 2 via normal paths NP(BD3O) and NP(BD3I) and the output terminal of the shared terminal OUT4 is connected to the logical circuit network 2 via a normal path NP(OUT4).

On the other hand, in the scan mode (2), the selectors SL2a and SL2b are switched to “1”. Therefore, the shared terminals OUT6 and OUT7 are connected to the output terminals of the scan chain SC1 and SC2 via the test paths TP(OUT6) and TP(OUT7).

As a consequence, the input terminal of the scan chain SC1 is connected to the input terminal IN5, the output terminal of the scan chain SC1 is connected to the shared terminal OUT6, the input terminal of the scan chain SC2 is connected to the input terminal IN2, and the output terminal of the scan chain SC2 is connected to the shared terminal OUT7.

With the above-mentioned connecting relationship, the scan test in the scan mode (2) is implemented.

As mentioned above, in the scan mode (2), the selectors complementarily select the normal path and the test path, depending on the scan mode (1).

Thus, with the scan test in the scan mode (2), the shared terminals OUT6 and OUT7 are connected to the scan chains SC1 and SC2 via the test path, and the connecting result is used for the scan test.

On the other hand, the input and output terminals of the shared terminals BD1 and BD3 and the output terminal of the shared terminal OUT4 are connected to the logical circuit network 2 via the normal paths, and can be observed even during the scan test in the scan mode (2).

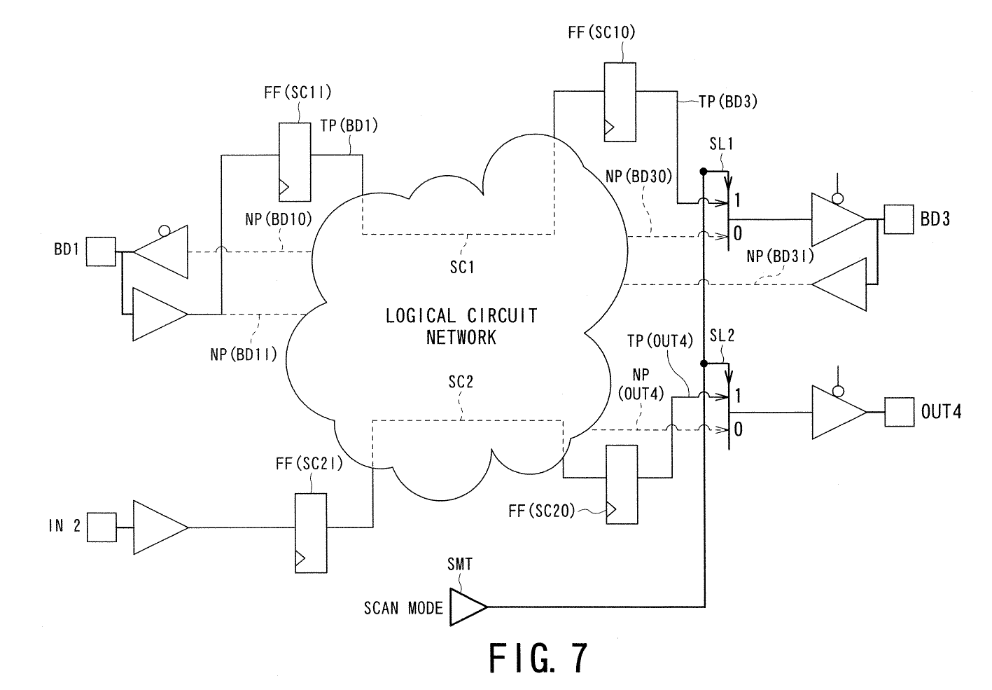

FIG. 7 shows an example of the configuration of a conventional semiconductor integrated circuit 100 having one scan mode according to a comparison of the first embodiment.

In the scan mode, selectors SL1 and SL2 are switched to “1”. The shared terminal BD1 is selected to the input terminal of the scan chain SC1, and the shared terminal BD3 is connected to the output terminal of the scan chain SC1. Similarly, the input terminal IN2 is connected to the input terminal of the scan chain SC2, and the shared terminal OUT4 is connected to the output terminal of the scan chain SC2.

Upon implementing the scan test in this state, the normal paths between the logical circuit network 2 and the shared terminal BD1, BD3, and OUT4 cannot be observed, and an unobserved part thus remains in the scan test.

On the other hand, the semiconductor integrated circuit 1 according to the first embodiment uses a plurality of scan modes (two scan modes in the examples shown in FIGS. 1 and 2) for implementation of the scan test. The test path is tested in one scan mode and the normal path is test in another scan mode. As a consequence, even when the shared terminal has two paths including the normal path connected to the logical circuit network 2 and the test path connected to the scan chain, all the paths can be tested without fail.

Thus, the fault detecting rate of the scan test can be improved.

### (2) Second Embodiment

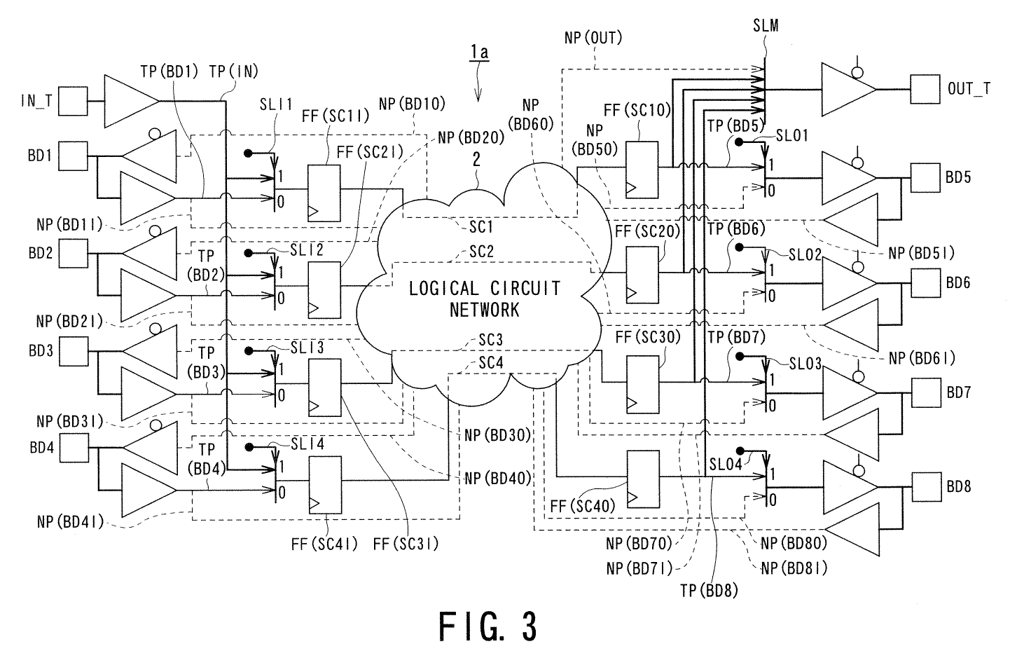

FIG. 3 is a diagram showing an example of the configuration of a semiconductor integrated circuit 1a according to a second embodiment of the present invention.

It is mainly different from the first embodiment that an input terminal IN_T for inputting a test signal to the scan chain is disposed, an input path TP(IN) connected to the input terminal IN_T is distributed into a plurality of connected paths and signals are input via a selector (first selector) connected to the input terminal of the scan chain.

Further, according to the second embodiment, the semiconductor integrated circuit la comprises an output terminal OUT_T connected to a selector SLM (third selector) for selecting one of test paths connected to the output terminal of the scan chain.

A selector (second selector) for selectively switching the test path and the normal path is disposed to the output terminal of the scan chain.

The above-mentioned configuration enables a larger number of scan chains and a larger number of scan modes. Therefore, in the example shown in FIG. 3, four scan chains SC1, SC2, SC3, and SC4 are disposed.

Note that, in the example shown in FIG. 3, all input and output terminals except for the input terminal IN_T and the output terminal OUT_T are set as bi-directional shared terminals BD and, alternatively, may mixedly include a mono-directional terminal.

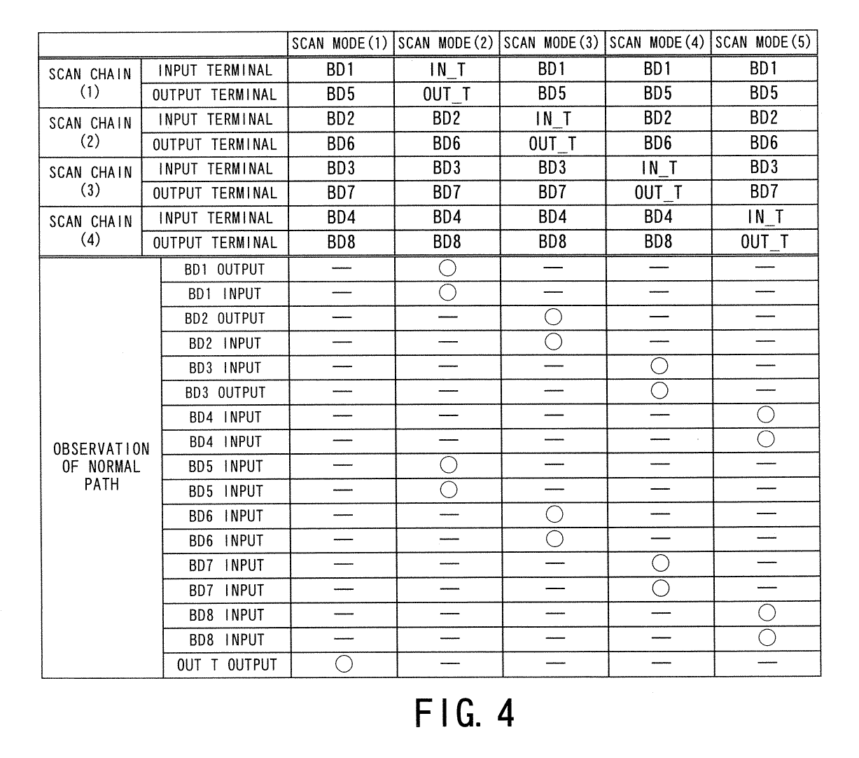

A description is given of the operation of the semiconductor integrated circuit 1a with the above-mentioned configuration with reference to FIGS. 3 and 4.

The semiconductor integrated circuit 1a according to the second embodiment can have a number of scan modes, larger than the number of the scan chains. In the example, as shown in FIG. 4, the scan test is performed to the four scan chains with five scan modes.

In the scan mode (1), four first-selectors SLI1, SLI2, SLI3, and SLI4 are switched to “0”. As a consequence, shared terminals BD1, BD2, BD3, and BD4 are connected to input terminals of the scan chains SC1, SC2, SC3, and SC4.

On the other hand, four second-selectors SLO1, SLO2, SLO3, and SLO4 are switched to “1”. As a consequence, shared terminals BD5, BD6, BD7, and BD8 are connected to output terminals of the scan chains SC1, SC2, SC3, and SC4.

Further, a third selector SLM selects a normal path NP(OUT) connected to the logical circuit network 2, and the normal path NP(OUT) is connected to the output terminal OUT_T.

With the above-mentioned connecting relationship, the scan test in the scan mode (1) is implemented.

The eight shared terminals BD1, BD2, BD3, BD4, BD5, BD6, BD7, and BD8 are connected to four scan chains via test paths TP, and the test paths TP are tested in the scan test.

However, it is not possible to observe, with the scan test in the scan mode (1), the normal paths NP(BD1O), NP(BD1I), NP(BD2O), NP(BD2I), NP(BD3O), NP(BD3I), NP(BD4O), NP(BD4I), NP(BD5O), NP(BD5I), NP(BD6O), NP(BD6I), NP(BD7O), NP(BD7I), NP(BD8O), and NP(BD8I) between the eight shared terminals and the logical circuit network 2.

After ending the scan test in the scan mode (1), the scan test in the scan mode (2) is implemented.

In the scan mode (2), the selection of the selector SLI1 on the input side of the scan chain SC1 is changed from “0” to “1”, and the selection of the selector SLO1 on the output side of the scan chain SC1 is changed from “1” to “0”. Further, the third selector SLM selects a test passage of TP(BD5) on the output side of the scan chain SC1. Other selectors (selectors on the input and output sides of the scan chains SC2, SC3, and SC4) are in the same status of the scan mode (1).

As a consequence, in the scan mode (2), the input terminal IN_T is connected to the input side of the scan chain SC1, and the output terminal OUT_T is connected to the output side of the scan chain SC1.

The shared terminal BD1 is connected to the logical circuit network 2 via the normal paths NP(BD1O) and NP(BDI1), and the shared terminal BD5 is connected to the logical circuit network 2 via normal paths NP(BD5O) and NP(BD5I).

Thus, the scan test in the scan mode (2) enables the observation of the normal paths NP(BD1O), NP(BD1I), NP(BD5O), and NP(BD5I), which cannot be observed in the scan mode (1).

As mentioned above, a pair of the shared terminals connected to the input and output sides of the scan chain is replaced to a pair of the input terminal IN_T and the output terminal OUT_T, thereby observing the normal path connected to the replaced shared terminal.

As shown in FIG. 4, the above-mentioned switching of the paths in the scan modes (3) to (5) enables the observation of all the normal paths of the shared terminals, which cannot be observed in the scan mode (1).

With the semiconductor integrated circuit 1a according to the second embodiment, similarly to the first embodiment, both the normal path and the test path connected to the shared terminal can be tested during the scan test. In addition, even when the semiconductor integrated circuit 1a has a large number of the scan chains, all the normal paths can be tested by repeating the simple scan-mode without complicated control.

### (3) Third Embodiment

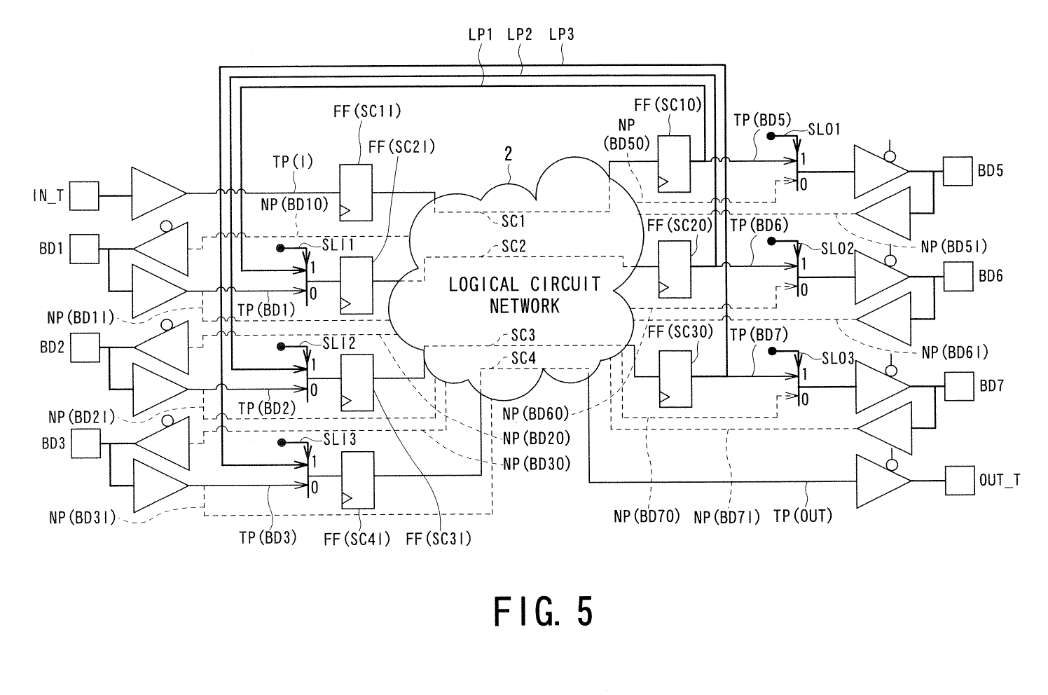

FIG. 5 is a diagram showing an example of the configuration of a semiconductor integrated circuit 1b according to a third embodiment of the present invention.

The semiconductor integrated circuit 1b according to the third embodiment comprises three types of first, second, and third scan chains.

An input side of a first scan-chains SC1 is directly connected to an input terminal IN_T, not via a selector, and an output side of the first scan-chains SC1 is connected to a feedback path LP.

Input sides of second scan-chains SC2 and SC3 are connected to a first selector, and output sides of the second scan-chains SC2 and SC3 are connected to the feedback path LP.

An input side of a third scan-chain SC4 is connected to the first selector, and an output side of the third scan-chain SC4 is directly connected to an output terminal OUT_T, not via the selector.

The first selector selectively switches a feedback path LP and a test path TP connected to the shared terminal to be connected to the input sides of the second and third scan chains.

Further, the second selector connected to the output sides of the first and second scan-chains switches the test path TP on the output sides of the scan chains and the normal path NP connected to the logical circuit network 2 to be connected to the shared terminal.

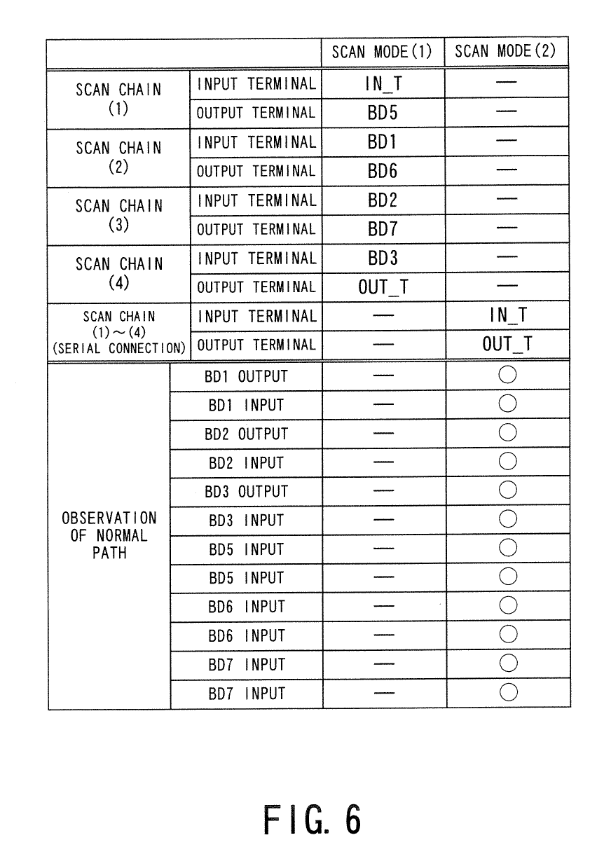

A description is given of the operation of the semiconductor integrated circuit 1b with the above-mentioned configuration with reference to FIGS. 5 and 6.

Referring to FIG. 6, the semiconductor integrated circuit 1b comprises two scan modes (1) and (2).

In the scan mode (1), first selectors SLI1, SLI2, and SLI3 select “0”. Further, second selectors SLO1, SLO2, and SLO3 select “1”. As a consequence, the scan chains form four paths flowing in parallel with each other from the left to the right, as shown in FIG. 5.

In the scan mode (1), all shared terminal BD1, BD2, BD3, BD4, BD5, BD6, and BD7 are used as input and output terminals of the scan chains. Therefore, test paths TP(BD1), TP(BD2), TP(BD3), TP(BD4), TP(BD5), TP(BD6), and TP(BD7) can be tested in the scan test.

On the other hand, normal paths NP(BD1O), NP(BD1I), NP(BD2O), NP(BD2I), NP(BD3O), NP(BD3I), NP(BD4O), NP(BD4I), NP(BD5O), NP(BD5I), NP(BD6O), NP(BD6I), NP(BD7O), and NP(BD7I) between the logical circuit network 2 and the shared terminals cannot be observed during the scan test in the scan mode (1).

After ending the scan mode (1), the mode shifts to the scan mode (2).

In the scan mode (2), the first selectors SLI1, SLI2, and SLI3 select “1”. Further, the second selectors SLO1, SLO2, and SLO3 select “0”. As a consequence, all the scan chains are serially connected via feedback paths LP1, LP2, and LP3, thereby forming one long scan chain having the input terminal IN_T corresponding to an input terminal thereof and the output terminal OUT_T corresponding to an output terminal thereof.

A shared terminal for input and output operation to/from the long scan chain does not intervene. Thus, in the scan mode (2), the shared terminal and the logical circuit network 2 can be connected via the normal path. All the normal paths of the shared terminal can be observed during the scan test in the scan mode (2), as shown in FIG. 6.

According to the third embodiment, even when a plurality of the scan chains exist, all the paths including the normal path can be tested in the two modes having the mode for individually testing the paths in parallel (scan mode (1)) and in the mode for cascade-connecting all of the plurality of the scan chains (scan mode (2)). Therefore, this is advantageous in the case in which a large number of scan modes cannot be set under some limitation.

Note that the present invention is not limited to the above embodiments and can be embodied by modifying the components without departing the essentials thereof in the implement. Further, the present invention can be embodied by properly combining a plurality of components disclosed in the embodiments. For example, some components may be deleted from all the components shown in the embodiments. Furthermore, the components in the different embodiments may be properly combined.

What is claimed is:

1. A semiconductor integrated circuit comprising:
a logical circuit network that implements predetermined processing;
a plurality of scan chains that are penetrated through the logical circuit network and test the logical circuit network in a plurality of test modes;
a plurality of shared terminals that share signals in a normal operating mode and in the plurality of the test modes, and input and output the signals; and
a plurality of selectors that selectively switch a normal path connected to the logical circuit network and a test path connected to the scan chain, and connect the switched path to the shared terminal,
wherein, when the selector selects the test path in one test mode, the selector selects the normal path in the other test modes.

2. The semiconductor integrated circuit according to claim 1,
Wherein the plurality of the test modes include a first test mode and a second test mode, and
the selector selects the test path in the first test mode and selects the normal path in the second mode.

3. The semiconductor integrated circuit according to claim 1, further comprising:
an input terminal that inputs the signal in the test mode;
an output terminal that outputs the signal in the test mode;
wherein,
the plurality of the selectors includes;
a plurality of first selectors that selectively switch one of a plurality of input paths distributed from the input terminal and one test path connected to the plurality of shared terminals, and connects the switched path to an input side of one of the scan chains;
a plurality of second selectors that selectively switch one of a plurality of normal paths connected to the logical circuit network and one test path connected to an output side of the scan chain, and connects the switched path to one of the shared terminal; and
a third selector that selects one of a plurality of normal paths connected to the logical circuit network and a plurality of test paths on output sides of the plurality of the scan chains, and connects the selected path to the output terminal, and
when one of the plurality of first selectors selects one of the input paths, another first selector selects the test path,
on the output side of the scan chain connected to the first selector that selects the test path, the second selector selects the test path and connects the selected test path to the shared terminal, and
on the output side of the scan chain connected to the first selector that selects the input path, the second selector selects the normal path and connects the selected normal path to the shared terminal, and the third selector selects the test path on the output side of the scan chain and connects the selected test path to the output terminal.

4. The semiconductor integrated circuit according to claim 1,
wherein, the plurality scan chains include a first scan chain, a plurality of second scan chains, and a third scan chain,
further comprising:
an input terminal that inputs a signal in the test mode and is connected to an input side of the first scan chain;
an output terminal that outputs the signal in the test mode and is connected to the output side of the third scan chain; and
a feedback path that feedbacks outputs of the first scan chain and the plurality of the second scan chains;
the plurality of the selectors include,
a plurality of first selectors that selectively switch the feedback path and a test path connected to the shared terminal, and connect the switched path to input sides of the plurality of the second scan chains and the third scan chain; and
a plurality of second selectors that selectively switch one of a plurality of normal paths connected to the logical circuit network and one test path connected to the output sides of the first scan chain and the plurality of the second scan chains, and connects the switched path to one of the shared terminals,
wherein, when the first selector selects the test path and connects the selected test path to one of the input sides of the plurality of second scan chains or the third scan chain, the second selector selects the test path connected to the output side of the corresponding scan chain and connects the selected test path to the shared terminal or the output terminal, and
when the first selector selects the feedback path to form a serial-connecting path of the first, second, and third scan chains from the input terminal thereof to the output terminal thereof, the second selector selects the normal path and connects the selected normal path to the shared terminal.

5. The semiconductor integrated circuit according to claim 1,
wherein, the plurality of the shared terminals include bi-directional input and output terminals.

6. A control method of a semiconductor integrated circuit, the semiconductor integrated circuit comprising a logical circuit network that implements predetermined processing, a plurality of scan chains that are penetrated through the logical circuit network and test the logical circuit network in a plurality of test modes, a plurality of shared terminals that share signals in a normal operating mode and in a test mode, and input and output the signals; and a plurality of selectors that selectively switch a normal path connected to the logical circuit network and a test path connected to the scan chain, and connect the switched path to the shared terminal,
the control method comprising:
selecting a test path in one test mode; and
selecting a normal path in the other test modes.

7. The control method of the semiconductor integrated circuit according to claim 6,
wherein,
the plurality of test modes include a first test mode and a second test mode, and
the selector selects the test path in the first test mode and selects the normal path in the second mode.

8. The control method of a semiconductor integrated circuit according to claim 6,
wherein,
the semiconductor integrated circuit includes an input terminal that inputs the signal in the test mode and an output terminal that outputs the signal in the test mode;
the plurality of the selectors includes;
a plurality of first selectors that selectively switch one of a plurality of input paths distributed from the input terminal and one test path connected to the plurality of shared terminals, and connects the switched path to an input side of one of the scan chains;
a plurality of second selectors that selectively switch one of a plurality of normal paths connected to the logical circuit network and one test path connected to an output side of the scan chain, and connects the switched path to one of the shared terminal; and
a third selector that selects one of a plurality of normal paths connected to the logical circuit network and a plurality of test paths on output sides of the plurality of the scan chains, and connects the selected path to the output terminal, and
when one of the plurality of first selectors selects one of the input paths, another first selector selects the test path,
on the output side of the scan chain connected to the first selector that selects the test path, the second selector selects the test path and connects the selected test path to the shared terminal, and
on the output side of the scan chain connected to the first selector that selects the input path, the second selector selects the normal path and connects the selected normal path to the shared terminal, and the third selector selects the test path on the output side of the scan chain and connects the selected test path to the output terminal.

9. The control method of a semiconductor integrated circuit according to claim 6,
wherein,
the plurality scan chains include a first scan chain, a plurality of second scan chains, and a third scan chain,
the semiconductor integrated circuit further comprises;
an input terminal that inputs a signal in the test mode and is connected to an input side of the first scan chain;
an output terminal that outputs the signal in the test mode and is connected to the output side of the third scan chain; and
a feedback path that feedbacks outputs of the first scan chain and the plurality of the second scan chains;
the plurality of the selectors include;
a plurality of first selectors that selectively switch the feedback path and a test path connected to the shared terminal, and connect the switched path to input sides of the plurality of the second scan chains and the third scan chain; and
a plurality of second selectors that selectively switch one of a plurality of normal paths connected to the logical circuit network and one test path connected to the output sides of the first scan chain and the plurality of the second scan chains, and connects the switched path to one of the shared terminals,
wherein, when the first selector selects the test path and connects the selected test path to one of the input sides of the plurality of second scan chains or the third scan chain, the second selector selects the test path connected to the output side of the corresponding scan chain and connects the selected test path to the shared terminal or the output terminal, and
when the first selector selects the feedback path to form a serial-connecting path of the first, second, and third scan chains from the input terminal thereof to the output terminal thereof, the second selector selects the normal path and connects the selected normal path to the shared terminal.

10. The control method of a semiconductor integrated circuit according to claim 6,
wherein, the plurality of the shared terminals include bi-directional input and output terminals.
